(19) United States
(12) Patent Application Publication
(10) Pub. No.: US 2005/0224863 A1
(43) Pub. Date: Oct. 13, 2005

(54) Semiconductor device and method of manufacturing the same

(76) Inventors: Katsuhiko Hieda, Yokohama-shi (JP); Yoshio Ozawa, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/088,000

(22) Filed: Mar. 24, 2005

(30) Foreign Application Priority Data
Mar. 26, 2004 (JP) 2004-093021

(51) Int. Cl. H01L 27/12

(52) U.S. Cl. 257/315

(57) ABSTRACT

A semiconductor device includes a semiconductor substrate, first isolation area on the substrate including first and second trenches, first insulating film in the trenches protruding above the surface, with respect to channel width direction, distance between first insulating film on first and second trenches at position higher than the surface being longer than the distance at a position of the surface, and a memory cell having the channel width direction and provided on the substrate including second insulating film on the surface between first and second trenches, control gate above second insulating film, floating gate between control gate and second insulating film, with respect to dimension in the direction, an upper side of floating gate facing control gate being larger than a lower side of floating gate facing second insulating film, and with respect to the direction, displacement of floating gate to first and second trenches being approximately equal.

### CROSS-REFERENCE TO RELATED APPLICATIONS

This application is based upon and claims the benefit of priority from prior Japanese Patent Application No. 2004-093021, filed Mar. 26, 2004, the entire contents of which are incorporated herein by reference.

### BACKGROUND OF THE INVENTION

1. Field of the Invention

The present invention relates to a semiconductor device comprising electrically rewritable semiconductor memory cells and a method of manufacturing the same.

2. Description of the Related Art

A nonvolatile semiconductor memory is one of the semiconductor memory devices. In recent years, the nonvolatile semiconductor devices are in increasing demand as data storage devices. As the typical electrically rewritable nonvolatile memories using floating-gate (FG) electrodes, NOR-type flash memory and NAND-type flash memory are known.

In order to increase the storage capacity of these flash memories, the dimensions of devices have been scaled down. However, shrinking the dimensions of devices have caused various problems, such as the increased aspect ratio of device structure, the effect on interference between adjacent FG electrodes, and the effect of variations in process on the injection of electrons into FG electrodes.

Especially, the large aspect of the device structure will lead to various problems. Therefore, efforts to control the aspect of the cell structure at low level have been made. Especially, in a shallow trench isolation (STI) structure, a structure is employed where a tunnel oxide film and a floating gate (FG) electrode are formed first, and an insulating film is filled in a trench formed in the STI area (Jpn. Pat. Appln. KOKAI Publication No. 08-017948).

FIGS. 18 to 20 are cross sectional views showing a conventional memory cell of the NAND type flash memory. FIG. 18 is cross sectional view in the direction of the bit line, FIG. 19 is a cross sectional view in the direction of the word line, and FIG. 20 shows an enlarged view of the region surrounded by a dot-and-slash line in FIG. 18. In these drawings, a reference numeral 310 denotes a silicon substrate, a reference numeral 311 denotes a gate insulating film, a reference numeral 312 denotes a tunnel insulating film, a reference numeral 313 denotes a FG electrode, a reference numeral 314 denotes a buried type isolation insulating film, a reference numeral 315 denotes an interpoly insulating film, a reference numeral 316 denotes a control gate (CG) electrode, a reference numeral 317 denotes a source/drain diffusion layer with a low impurity concentration, a reference numeral 318 denotes a side wall insulating film, a reference numeral 319 denotes a source/drain diffusion layer with a high impurity concentration, a reference numeral 320 denotes an interlayer insulating film, a reference numeral 321 denotes a plug, and a reference numeral 322 denotes a bit line.

In the above conventional memory cell structure, the tunnel insulating film 312 and the FG electrode 313 are formed in prior to the isolation insulating film 314 (STI), and after the formation of the isolation insulating film 314 (STI), the side surface of the FG electrode 313 is exposed, thereby the coupling capacitance between the FG electrode 313 and the CG electrode 316 is increased. However, the above memory cell structure has the following problem.

As the miniaturization of devices progress, the aspect of the STI trench becomes higher, and it becomes difficult to fill the STI trench with the isolation insulating film 314. For example, it is difficult to fill the STI trench with an SiO₂ film (isolation insulating film 314) using the conventional HDP (High Density Plasma)-CVD process.

Therefore, as a process to full the STI trench with an insulating film, a process is proposed where a solution of polysilazan or the like is applied on a silicon substrate, thereby the STI trench is filled with the solution, thereafter, the solution is changed into an SiO₂ film by high temperature processing (Jpn. Pat. Appln. KOKAI Publication No. 10-116427).

However, it is known that through etching of the silicon substrate 310 using plasma that is carried out at the formation of the STI film, high temperature vapor oxidation that is carried out at the formation of the isolation insulating film 314 and the like, the reliability of the tunnel insulating film 312 that has been formed in prior is deteriorated by plasma atmosphere and hydrogen in oxidizing atmosphere.

Accordingly, the formation conditions of the isolation insulating film 314 are optimized, and process conditions are optimized by making the temperature at the formation of the STI film low and so forth. However, it is difficult to find out preferred process conditions.

The deterioration of reliability of the tunnel insulating film 312 may cause operation failures of products such as flash memories and the like, which has been a big problem.

On the other hand, a process has been already proposed where the formation process of the tunnel insulating film 312 and the FG electrode 313 is carried out after the formation process of the isolation (STI). This process does not see the above problem. However, in order to carry out this process, highly precise alignment (OL) of the isolation insulating film 314 (STI) and the FG electrode 313 is required. However, it is difficult to carry out such highly precise OL.

### BRIEF SUMMARY OF THE INVENTION

According to an aspect of the present invention, there is provided a semiconductor device comprising: a semiconductor substrate; a first isolation area provided on the semiconductor substrate, the first isolation area comprising first and second trenches provided on a surface of the semiconductor substrate; and a first insulating film provided in the first and second trenches and protruding above the surface of the semiconductor substrate, and with respect to a channel width direction, a distance between the first insulating film on the first trench and the first insulating film on the second trench at position higher than the surface of the semiconductor substrate being longer than the distance at a position of the surface; and an electrically rewritable semiconductor memory cell having the channel width direction and provided on the substrate, the semiconductor memory cell comprising a second insulating film provided on the surface of the semiconductor substrate between the first trench and the second trench; a control gate electrode provided above the second insulating film; a floating gate electrode provided between the control gate electrode and the second insulating film, with respect to dimension in the channel width direction, an upper side of the floating gate electrode facing the control gate electrode being larger than a lower side of the floating gate electrode facing the second insulating film, and with respect to the channel width direction, displacement of the floating gate electrode to the first and second trenches being approximately equal; and a third insulating film provided between the floating gate electrode and the control gate electrode.

According to an aspect of the present invention, there is provided a method of manufacturing a semiconductor device comprising: forming a first insulating film on a semiconductor substrate; forming first and second trenches penetrating the first insulating film and reaching a halfway depth of the semiconductor substrate by etching the first insulating film and the semiconductor substrate; filling the first and second trenches with a second insulating film; removing the first insulating film by chemical solution process; forming a third insulating film on a surface of the semiconductor substrate between the first trench and the second trench, the surface being exposed by removing the first insulating film; forming a floating gate electrode on the third insulating film; the floating gate electrode having a surface which is approximately flush with an upper surface of the second insulating film; forming a fourth insulating film on the floating gate electrode; and forming a control gate electrode on the fourth insulating film.

According to another aspect of the present invention, there is provided a method of manufacturing a semiconductor device comprising: forming a first insulating film on a first area, a second area and a third area of a semiconductor substrate; forming an oxidation prevention area in the third area; removing the first insulating film in the second and third areas; forming a second insulating film by oxidizing the first, second and third areas, the second insulating film having a film thickness distribution wherein the second insulating film becomes thinner in the order of the first area, the second area, and the third area, and the second insulating film in the first area including the first insulating film; forming a first gate electrode on the second insulating film; forming a third insulating film on the first gate electrode in the second area; and forming a second gate electrode on the third insulating film in the second area and on the first gate electrode in the first and third areas.

According to another aspect of the present invention, there is provided a method of manufacturing a semiconductor device comprising: forming a first insulating film on a first area, a second area and a third area of a semiconductor substrate; forming an oxidation prevention area in the third area; forming first and second trenches penetrating the first insulating film and reaching a halfway depth of the semiconductor substrate by etching the first insulating film in the second area and the semiconductor substrate; filling the first and second trenches with a second insulating film; removing the first insulating film in the second and third areas by chemical solution process; forming a third insulating film by oxidizing the first, second and third areas, the third insulating film having a film thickness distribution wherein the third insulating film becomes thinner in the order of the first area, the second area, and the third area, and the third insulating film in the first area including the first insulating film; forming a first gate electrode on the third insulating film, the first gate electrode having a surface which is approximately flush with an upper surface of the second insulating film in the second area; forming a fourth insulating film on the first gate electrode in the second area; and forming a second gate electrode on the fourth insulating film in the second area and on the first gate electrode in the first and third areas.

### BRIEF DESCRIPTION OF THE SEVERAL VIEWS OF THE DRAWING

FIGS. 1A and 1B are a plane view and an equivalent circuit diagram of an NAND flash memory according to an embodiment of the present invention.

FIG. 2 is a part of a B-B′ cross sectional view shown in FIG. 1A.

FIGS. 3A and 3B are an A-A′ cross sectional view shown in FIG. 1A and an enlarged cross sectional view of a part shown in FIG. 2.

FIGS. 4A to 4G are plane views and cross sectional views for explaining a method of manufacturing NAND flash memory according to the embodiment.

FIGS. 5A to 5G are plane views and cross sectional views for explaining a method of manufacturing NAND flash memory according to the embodiment following FIGS. 4A to 4G.

FIGS. 6A to 6G are plane views and cross sectional views for explaining a method of manufacturing NAND flash memory according to the embodiment following FIGS. 5A to 5G.

FIGS. 7A to 7G are plane views and cross sectional views for explaining a method of manufacturing NAND flash memory according to the embodiment following FIGS. 6A to 6G.

FIGS. 8A to 8G are plane views and cross sectional views for explaining a method of manufacturing NAND flash memory according to the embodiment following FIGS. 7A to 7G.

FIGS. 9A to 9G are plane views and cross sectional views for explaining a method of manufacturing NAND flash memory according to the embodiment following FIGS. 8A to 8G.

FIGS. 10A to 10G are plane views and cross sectional views for explaining a method of manufacturing NAND flash memory according to the embodiment following FIGS. 9A to 9G.

FIGS. 11A to 11G are plane views and cross sectional views for explaining a method of manufacturing NAND flash memory according to the embodiment following FIGS. 10A to 10G.

FIGS. 12A to 12G are plane views and cross sectional views for explaining a method of manufacturing NAND flash memory according to the embodiment following FIGS. 11A to 11G.

FIGS. 13A to 13G are plane views and cross sectional views for explaining a method of manufacturing NAND flash memory according to the embodiment following FIGS. 12A to 12G.

FIGS. 14A and 14B are cross sectional views for explaining an example of hybrid STI filling technology.

FIGS. 15A and 15B are cross sectional views for explaining another example of hybrid STI filling technology.

FIGS. 16A to 16D are cross sectional views corresponding to FIGS. 4B and 4G when an isotropic etching amount of an isolation insulating film is increased.

FIGS. 17A to 17D are cross sectional views corresponding to FIGS. 13B and 13G when an isotropic etching amount of an isolation insulating film is increased.

FIG. 18 is a cross sectional view of a memory cell of a conventional NAND type flash memory in a bit line direction.

FIG. 19 is a cross sectional view of a memory cell of a conventional NAND type flash memory in a word line direction.

FIG. 20 is an enlarged view of the portion entangled in a dash-dotted line shown in FIG. 18.

FIG. 21 is a schematic diagram showing a memory card with an NAND type flash memory according to the embodiment.

FIG. 22 is a schematic diagram showing a memory card without a controller.

FIG. 23 is a schematic diagram showing a memory chip with a control circuit.

### DETAILED DESCRIPTION OF THE INVENTION

Embodiments of the present invention are explained below with reference to the accompanying drawings.

### First Embodiment

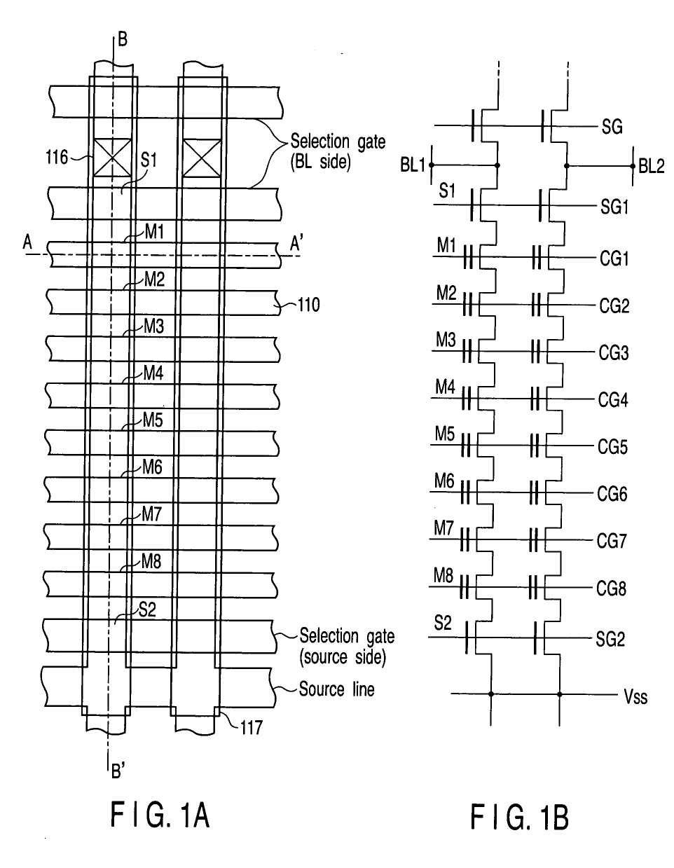

FIGS. 1A and 1B are diagrams showing an NAND flash memory according to an embodiment of the present invention. FIG. 1A is a plane view of a memory cell of an NAND flash memory, while FIG. 1B is an equivalent circuit diagram of the memory cell.

In FIGS. 1A and 1B, M1 to M8 shows nonvolatile memory cell portions, S1 and S2 show selection transistor portions, CG1 to CG8 show control gates, SG1 and SG2 show selection gates, BL1 and BL2 show bit lines, and Vss shows a source voltage.

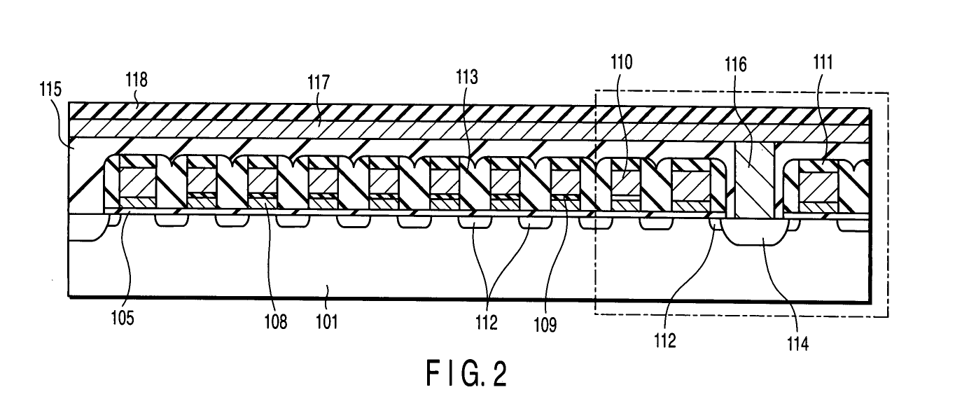

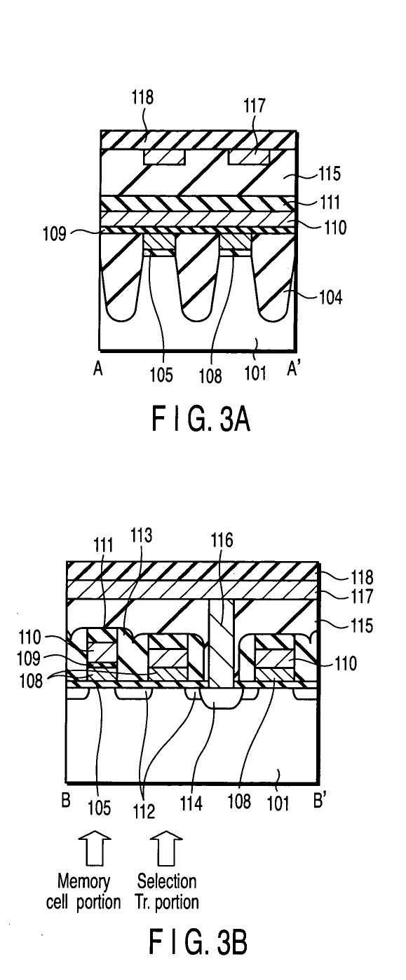

FIG. 2 is a B-B′ cross sectional view shown in FIG. 1A, FIG. 3A is an A-A′ cross sectional view shown in FIG. 1A, and FIG. 3B is an enlarged cross sectional view of a part shown in FIG. 2. However, in these figures, only a wire layer to the word lines and the bit lines is shown, while contacts and the wire layer of a metal wiring portion and higher, and a passivation layer are omitted herein.

In the figures, reference numerals 101 is a P type silicon substrate, reference numerals 104 is an isolation insulating film for filling an isolation trench (STI trench), reference numerals 105 is a tunnel insulating film, reference numerals 108 is an electrode (an FG electrode in memory cell portion, the first gate electrode in control circuit portion), reference numerals 109 is an interpoly insulating film provided between FG electrode and CG electrode, reference numerals 110 is an electrode (a CG electrode (word line) in memory cell portion, the second gate electrode in control circuit portion), reference numerals 111 is a gate cap insulating film, reference numerals 112 is a low impurity concentration source/drain diffusion layer (n⁻ type layer), reference numerals 113 is a side wall insulating film, reference numerals 114 is a high impurity concentration source/drain diffusion layer (n⁺ type layer), reference numerals 115 is an interlayer insulating film, reference numerals 116 is a filling layer (plug) to bit line contact, reference numerals 117 is a bit line, and reference numerals 118 is an interlayer insulating film.

As shown in FIG. 3A, the FG electrode 108 of the memory cell portion is electrically separated by the first isolation area (STI) formed on the surface of the silicon substrate 101.

The first isolation area comprises the isolation insulating film 104 which is provided in plural trenches (STI trenches) formed on the surface of the silicon substrate 101 and the insides thereof, and protrudes above the surface of the silicon substrate 101. The isolation insulating film 104 protrudes about 30 nm from the surface of the silicon substrate 101.

In the present embodiment, the isolation insulating film 104 is a silicon oxide film, while other insulating films may be employed. Further, peripheral circuits not shown therein are electrically separated by the second isolation area (STI) in the same manner as the above.

The CG electrode 110 is formed, via the interpoly insulating film 109, on the FG electrode 108. On the FG electrode 108 of the selection transistor portion, the gate electrode 110 is formed, without the interpoly insulating film 109 therein.

Further, the FG electrode 108 is formed on an AA (Active Area) area. The plane shape of the FG electrode 108 is nearly of a square. Two sides of the FG electrode 108 are so formed as to self-align with the STI area. Therefore, with respect to the channel width direction, the displacement amount of the FG electrode 108 to the STI trench becomes approximately equal. Remaining two sides of the FG electrode 108 are so formed as to self-align with the CG electrode 110. Therefore, with respect to the channel length direction, the displacement amount of the FG electrode 108 to the CG electrode 110 becomes approximately equal.

The isolation area (STI) is formed in prior to the tunnel insulating film 105 and the FG electrode 108. Because the isolation area is formed in advance, even when the isolation insulating film 104 is formed using high temperature process, the tunnel insulating film 105 and the FG electrode 108 are not acquire any bad influence. By forming the isolation insulating film 104 using high temperature process, deterioration of the shape of the isolation insulating film 104 is prevented.

Further, as the interpoly insulating film 109 between the FG electrode 108 and the CG electrode 110, a high-k film is used. Therefore, without forming the CG electrode 110 on the side wall of the FG electrode 108, the capacitance between the FG electrode 108 and the CG electrode 110 increases.

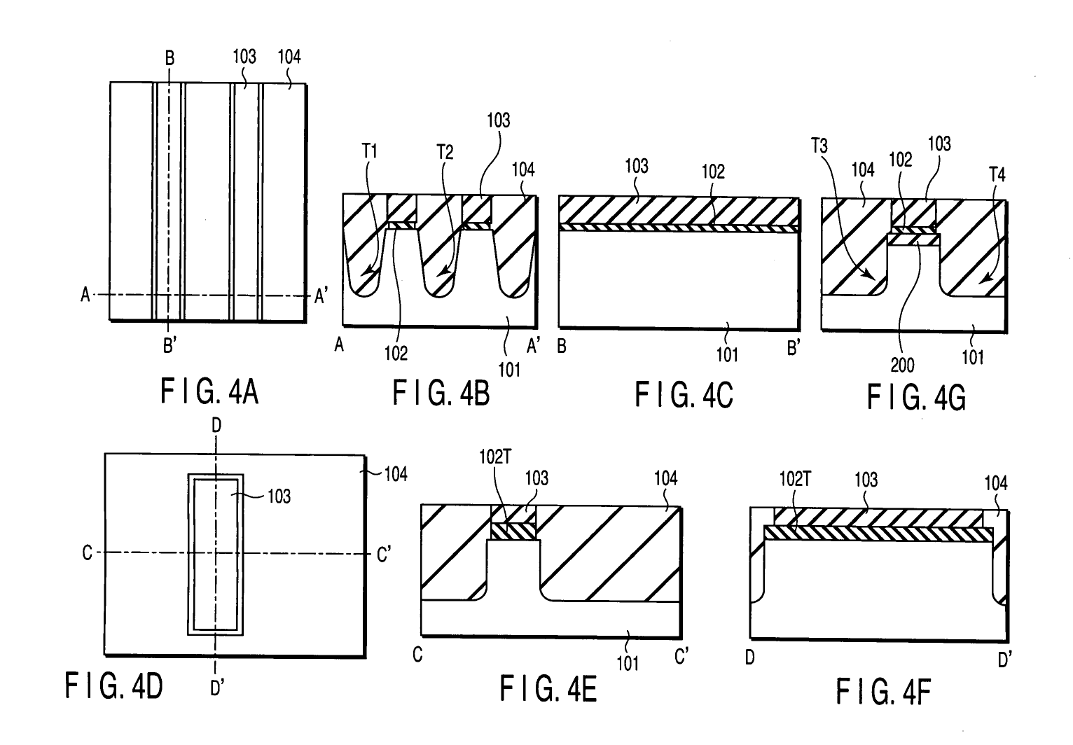

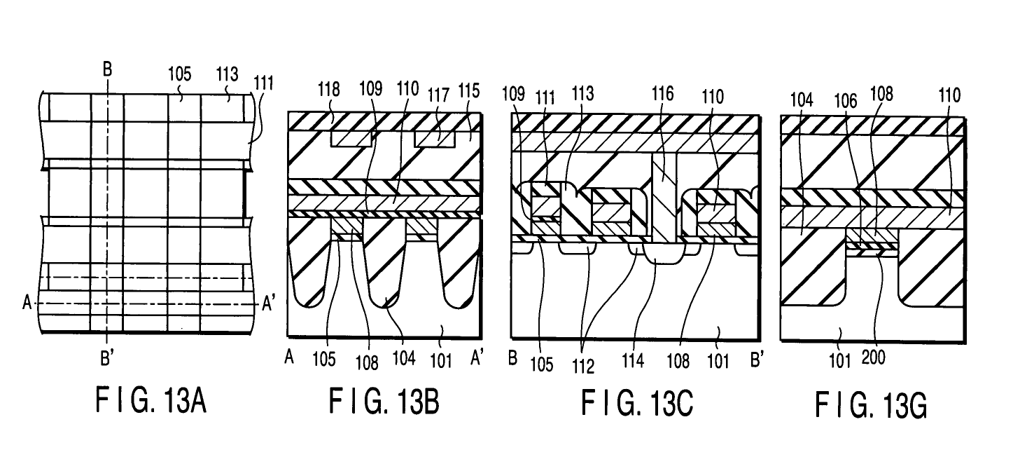

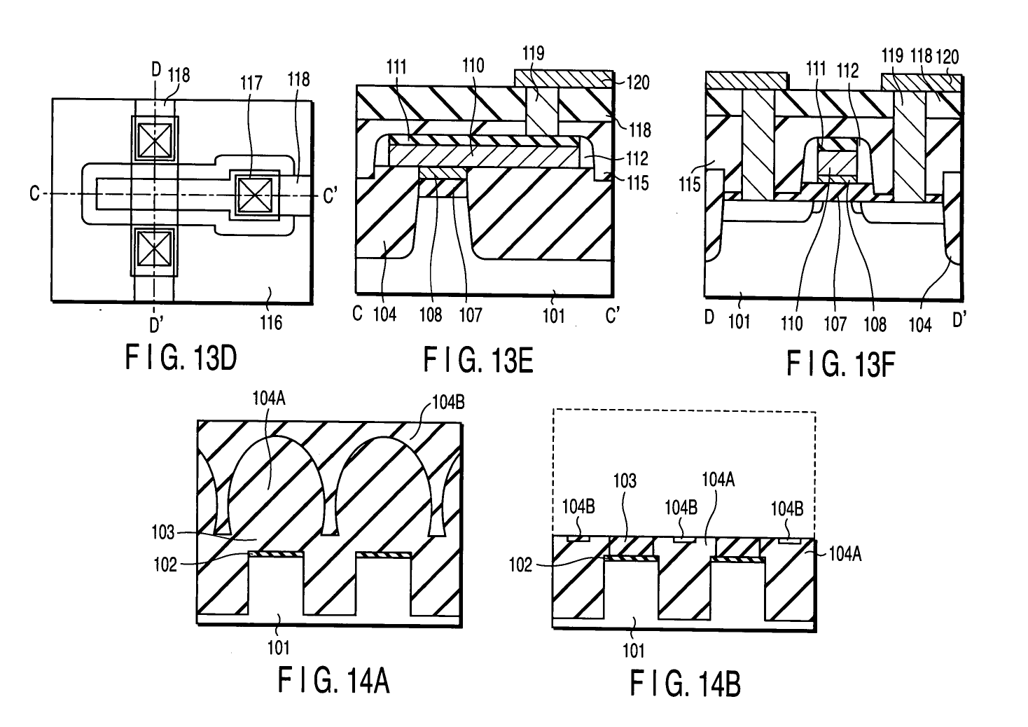

Next, a method of manufacturing NAND flash memory of the present embodiment is explained, by reference to FIGS. 4A to 4G and FIGS. 13A to 13G, hereinafter. Each FIG. A is a plane view of a part shown in FIG. 1, each FIG. B is an A-A′ cross sectional view of each FIG. A, each FIG. C is a B-B′ cross sectional view of each FIG. A, each FIG. D is a plane view of an example of a high voltage circuit portion of the circuit control portion formed on a same chip, each FIG. E is a C-C′ cross sectional view of each FIG. D, each FIG. F is a D-D′ cross sectional view of each FIG. D, and each FIG. G is a logic circuit portion of a peripheral circuit portion where a thinner gate insulating film than a tunnel insulating film is used.

First, as shown in FIGS. 4A to 4G, a P type silicon substrate 101 is prepared, thereafter, by use of lithography process, ion implantation process and anneal process, a P well and an N well (not shown) are formed selectively on a desired position on the surface of the silicon substrate 101.

Next, on the surface of the silicon substrate 101, a silicon oxide film 102T whose film thickness is for example about 40 nm is formed. The surface of the silicon substrate 101 on which the silicon oxide film 102T is formed is the area where a gate insulating film of the high voltage circuit portion is formed. Thereafter, by use of lithography process and chemical solution etching process, the silicon oxide film 102T in the memory cell area and the peripheral circuit logic portion is removed, and the surface of the silicon substrate 101 is exposed. Next, a thermal oxide film 102 whose film thickness is for example about 3 nm is formed.

Next, into a desired area to which a thin gate insulating film is to be formed, for example, nitrogen ion is implanted. The purpose of the ion implantation is to form a thin oxide film when a tunnel insulating film is formed in a later step. For this purpose, for example, using a resist film (not shown) as a mask, under the conditions of about dose amount 1×10¹⁴ cm²-5×10¹⁵ cm², nitrogen ions are implanted into a vicinity of the surface of the silicon substrate 101 by ion implantation process, thereby an area including nitrogen in the surface of the silicon substrate 101 (oxidation prevention area) 200 is formed.

Further, before forming the thermal oxide film 102, by other method than ion implantation process, a thin oxidation prevention area 200 may be formed on the surface of the silicon substrate 101. For example, a film that can suppress oxidation may be deposited. The film is, for example, a film having a nitrogen concentration enough to prevent oxidation.

Thereafter, on the entire surface, a silicon nitride film (Si₃N₄ film) 103 whose film thickness is for example about 45 nm is formed by LP-CVD process. On the silicon nitride film 103, a CVD-SiO₂ film (not shown) whose thickness is for example about 200 nm is deposited. Next, by use of photolithography process and RIE process, with a resist pattern not shown as a mask, the CVD-SiO₂ film, the silicon nitride film 103, a thermal oxide film 102, 102T, and the silicon substrate 101 are etched sequentially, and thereby STI trenches are formed. In the figure, for simplicity of explanations, reference numerals T1 to T4 are allotted to only four STI trenches (first trench to fourth trench).

The depth of the STI trenches is, for example, a depth of about 200 nm from the surface of the silicon substrate 101. The width of the STI trenches is, for example, about 70 nm (memory cell portion). Of course, the STI trenches are trenches for isolations, therefore STI trenches of various width values are formed on the surface of the silicon substrate 101.

Here, an example is shown where the CVD-SiO₂ film formed on the silicon nitride film (Si₃N₄ film) 103 is used as an etching mask member of the silicon substrate 101. Thereby, film thickness reduction of the silicon nitride film 103 during the etching of the silicon substrate 101 becomes small.

Further, herein, as an STI trench, a trench having tapered side walls where the trench width becomes slightly narrower toward the depth direction is shown as an example, meanwhile, a trench having nearly vertical side walls may be employed too. Further, round shape of a radium about 5 nm may be provided at bottom corners of an STI trench (not shown).

An STI trench of such a shape will improve filling property. That is, the inside of the STI trench is easily filled with an insulating film (isolation insulating film). Further, stress concentration at bottom corners of the STI trench will be released. Further, in later step, processing of an electrode including side walls of trench is easily carried out.

The side surfaces of the STI trench formed on the surface of the silicon substrate 101 are oxidized by normal thermal oxidation method, as a result, a thermal oxidation film of a film thickness about 3 nm (not shown) is formed on the side surfaces of the STI trench.

Here, in the case where the side surfaces of the STI trench is oxidized by oxidation method using oxygen radical in the place of the thermal oxidation method, a silicon oxidation film is formed without any influence of the plain orientation of silicon (Si). Therefore, a uniform and high quality silicon oxide film is formed on the side surfaces of the STI trench. Further, the side surfaces of the STI trench may be oxidized by ISSG (In-Situ Steam Generation) method.

Next, impurity ions are implanted into the isolation area of a transistor in a desired area by ion implantation process using a resist pattern (not shown) formed by lithography process as a mask, thereafter, activation annealing of the impurity ions implanted into the isolation area is carried out. As a result, a field reverse prevention impurity layer (not shown) of the isolation area of the transistor is formed in the desired area.

Next, an insulating film (isolation insulating film) 104 is deposited on the entire surface so as to fill the STI trenches, thereafter, the isolation insulating film 104 is etched back by CMP process so that the surface of the silicon nitride film 103 and the surface of the isolation insulating film 104 should be at an almost same height.

Here, in the case where the aspect ratio of the STI trench is high, as the isolation insulating film 104, an HDP-CVD-SiO₂ film may be used, or an application film made of polysilazan may be used. It is important to fill evenly STI trenches corresponding to a wide STI width and STI trenches corresponding to a narrow STI width at the same time.

As the miniaturization progress, the aspect ratio becomes higher, and it becomes difficult to fill the STI trenches with an insulating film. Therefore, it is difficult to preferably fill the STI trench insides only by the HDP-CVD-SiO₂ film. In such a case, it is better to use a hybrid STI filling technology which is a one of the new filling technology. Hereinafter, the hybrid STI filling technology is explained in details.

In the hybrid STI filling technology, as shown in FIG. 14A, the lower portion of the STI trench is filled with an HDP-CVD-SiO₂ film 104A, the upper portion of the STI trench is filled with an SiO₂ film 104B formed by coating technology.

The filling of the upper portion of the STI trench is performed, for, example, by forming a film of silazane-perhydride polymer (hereinafter referred to as a PSZ film) having a thickness of, for example, about 400 nm on a region including the STI trench by coating method.

After formation of the PSZ film, a baking treatment in which the solvent is evaporated at about 150° C. is carried out for about 3 minutes. The coating technology exhibits satisfactory filling properties. On that account, a narrow STI trench having a width of about 70 nm can be filled with the PSZ film free from void.

Next, the PSZ film is converted into the SiO₂ film 104B. The process can be explained by chemical formula (1) given below:
SiH₂NH+2O→SiO₂+NH₃ (1)

That is, the conversion of PSZ film into the SiO₂ film 104B arises from the generation of SiO₂ and NH₃ (ammonia gas) cased by reaction between the PSZ film and oxygen (O) generated by the decomposition of the water vapor (H₂O+O₂).

At that time, as the surface of the silicon substrate 101 in the active area (element forming region) is covered with the silicon nitride film (Si₃N₄ film) 103, the surface of the silicon substrate 101 in the active area is not oxidized.

In order to bring about the chemical reaction referred to above, it suffices to carry out a combustion oxidation for about 30 minutes under a water vapor atmosphere of about 200° C. to 600° C. For example, if the combustion oxidation is carried out at 400° C. for about 30 minutes, the conversion from the Si—N bond into the Si—O bond is promoted within the PSZ film. Accordingly, the PSZ film buried in the STI trenches having various widths is converted into the SiO₂ film to the extent that event the PSZ film on the bottom of the STI trench is completely converted into the SiO₂ film.

In the step of the combustion oxidation, it is possible to employ a so-called “two-stage oxidation method” in which the oxidizing process is carried out first for about 30 minutes under the atmosphere containing a water vapor of about 400° C., thereafter, atmosphere is changed to an oxygen atmosphere, further, the temperature is elevated to high temperatures of about 800° C. so as to carry out the oxidizing process under the oxygen atmosphere for about 30 minutes.

In the case of employing the two-stage oxidizing method described above, the efficiency of the conversion from the PSZ film into the SiO₂ film 115B is enhanced. If the conversion efficiency is enhanced, the impurity such as carbon (C) remaining in the PSZ film is removed.

The two-stage oxidizing method is a method that is particularly effective for the conversion of the PSZ film into a SiO₂ film. It is important to hold the PSZ film for a certain time under the water vapor atmosphere at a temperature that the conversion from the PSZ film into the SiO₂ film is starts (for example, about 400° C.).

When it comes to the water vapor atmosphere, a water vapor atmosphere having a high water concentration formed by hydrogen combustion oxidation or WVG (Water Vapor Generator) is suitable for the conversion of the PSZ film into the SiO₂ film. It is desirable for the water concentration to be 80% or higher.

Next, a heat treatment under an inert gas atmosphere such as a nitrogen gas atmosphere is carried out for about 30 minutes at an arbitrary temperature falling within a range of between 700° C. and 1,000° C., e.g., at the temperature of about 850° C. By the heat treatment (densifying treatment), NH₃ and H₂O remained in the SiO₂ film 104B (SiO₂ film converted from the PSZ film) are released to the outside so as to densitfy the SiO₂ film 104B. Accordingly, the leakage current in the SiO₂ film 115B is reduced.

In the case Where the heat treatment is carried out under the oxygen atmosphere at the temperature of about 800° C., the impurity concentration such as the carbon (C) concentration within the SiO₂ film 104B is reduced. Accordingly, the leakage current is further reduced, and also fixed charge at the interface between the SiO₂ film 104B and the silicon substrate 101 is reduced.

The heat treatment employed in the densifying process of the SiO₂ film 104B includes another heat treatment such as an RTA (Rapid Thermal Annealing) and RTO (Rapid Thermal Oxidation) in addition to the heat treatment using the ordinary furnace. In the case of employing the RTA method, a high temperature heat treating process can be carried out under a higher temperature in a shorter time, compared with the heat treatment using the ordinary furnace.

Next, as shown in FIG. 14B, the SiO₂ films 104A and 104B are planarized by CMP process and the surface of the silicon nitride film 104A is exposed. After the planarization by CMP process, a heat treatment under a nitrogen gas (N₂) atmosphere of 850° C. may be carried out.

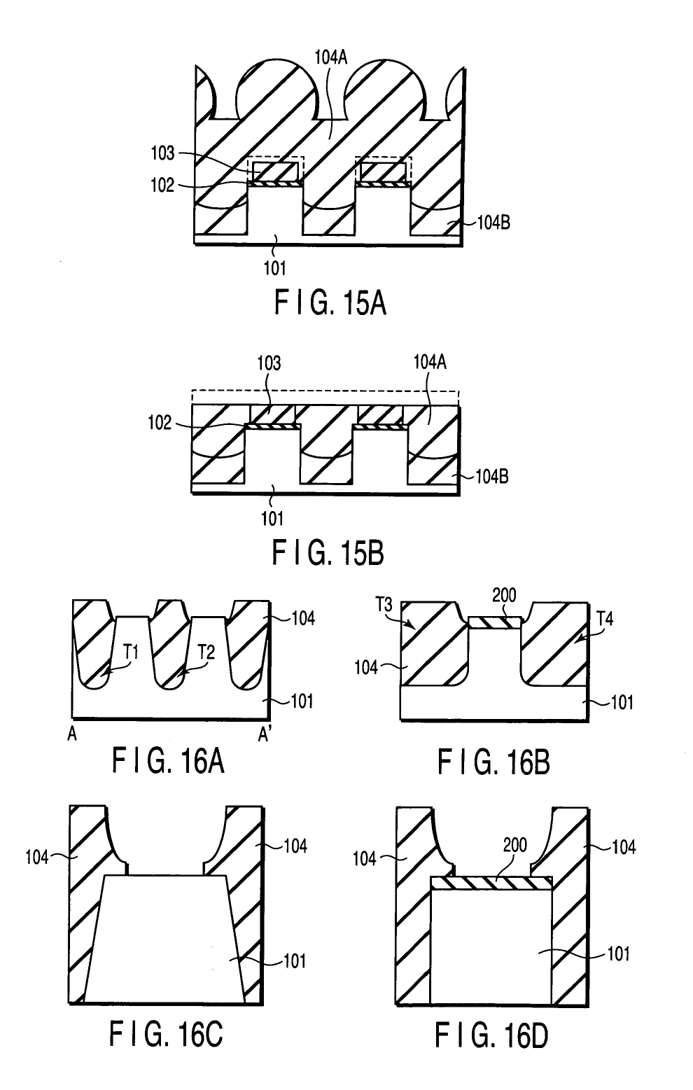

It is possible for the STI trench to be filled with the coated film alone. Also, it is possible to change the burying order. For example, as shown in FIGS. 15A and 15B, a coated film such as a PSZ film is formed in the STI trench, thereafter, a suitable heat treatment is carried out so as to convert the PSZ film into the SiO₂ film 104B, further, the HDP-CVD-SiO₂ film 104A is formed on the SiO₂ film 104B so as to permit the STI trench to be filled with the SiO₂ film 115A. Thereafter, the surface is planarized by, for example, the CMP process.

With progress of the miniaturization in the width of the STI trench from 110 nm to 70 nm, 50 nm and, further, to 40 nm, it is rendered difficult for the STI trench to be filled with the HDP-SiO₂ film. How to fill a fine STI trench is an important question on the manufacturing process.

Further, an oxide film that is formed by a method where a polysilazan film or an 03/TEOS-CVD-SiO₂ film and the like are filled in the STI trenches, then water vapor oxidation at for example about 900° C. is carried out may work as an oxide film of side surfaces of the STI trenches.

Thereby, the decrease of AA width is reduced. Further, by heat treatment at a high temperature, the film quality of the isolation insulating film 104 filled in the STI trench insides is improved. The improvement of film quality of the insulating film prevents the isolation insulating film 104 from thinning in the later chemical etching process for instance.

Further, before filling the insulating film into the STI trench insides, for example, as shown in broken lines in FIG. 15, what is called “pull-back” of the silicon nitride film 103, where the top surface of the silicon nitride film 103 is pulled back about 5 nm, may be carried out. Etching of the silicon nitride film 103 is carried out, for example, by use of a hot phosphoric acid solution at about 160° C.

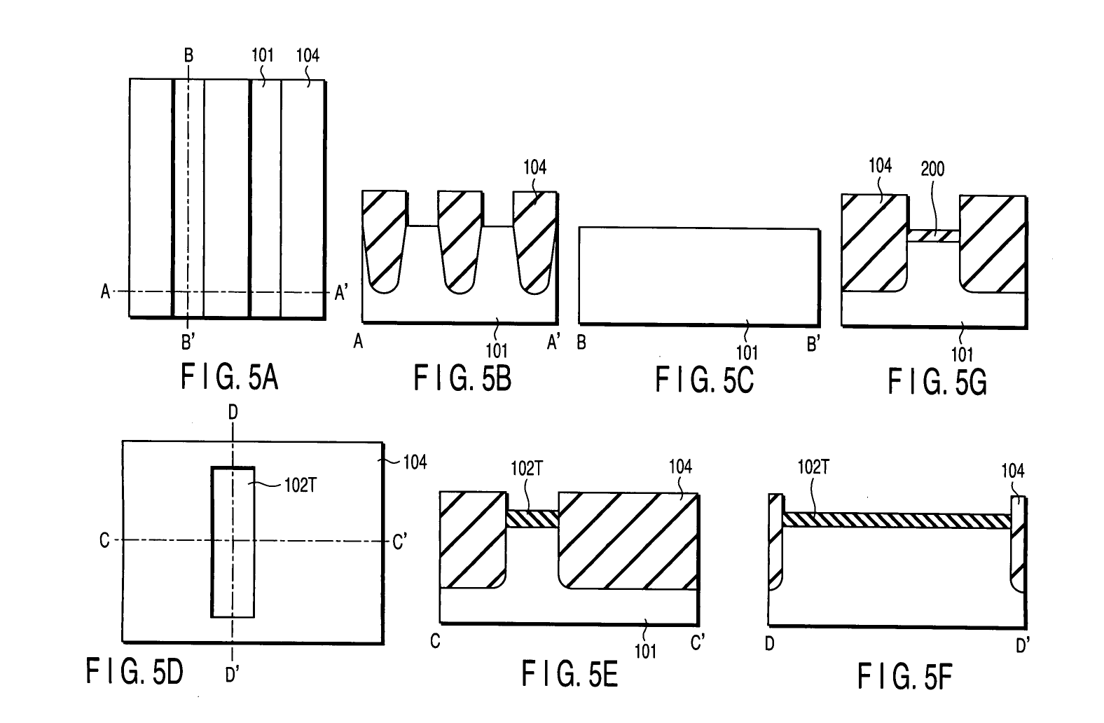

Next, as shown in FIGS. 5A to 5G, by use of the hot phosphoric acid solution, the silicon nitride film 103 is removed, thereafter, by use of a diluted HF solution or the like, the thermal oxide film 102 is removed. By this chemical solution process, a thick silicon oxide film 102T in the high voltage circuit portion is etched too. As a result, the film thickness of the silicon oxide film 102T after the chemical solution process becomes about 35 nm.

Further, in a case where the thermal oxide film 102 is removed by diluted HF solution or the like, the insulating film (isolation insulating film) 104, which is the silicon oxide film is etched isotropically.

Accordingly, in the memory cell portion, actually, as shown in FIG. 16A, with respect to the channel width direction of the memory cell, the distance between the isolation insulating film 104 (first insulating film) on the STI trench T1 (first trench) and the isolation insulating film 104 (first insulating film) on the STI trench T2 (second trench) becomes longer at the position higher than the surface of the silicon substrate 101 than at the position of the surface. In FIG. 16A, the distance of becomes longer toward the above (as farther away from the substrate surface).

In the same manners, at the peripheral circuit portion, as shown in FIG. 16B, with respect to the channel width direction of the MOS transistor, the distance between the isolation insulating film 104 (second insulating film) on the STI trench T3 (third trench) and the isolation insulating film 104 (second insulating film) on the STI trench T4 (fourth trench) becomes longer at the position higher than the surface of the silicon substrate 101 than at the position of the surface. In FIG. 16B, the distance becomes longer toward the above (as farther away from the substrate surface).

Further, by application of the “pull-back” shown in FIGS. 15A and 15B, to FIGS. 16A and 16B, as shown in FIGS. 16C and 16D, there is no need to expose the side surfaces of the silicon substrate 101. In such shapes, the edges of the silicon substrate 101 in the active area are covered with the isolation insulating film 104, and the tunnel insulating film 106 is not formed on the edges of the silicon substrate 101 in the active area. Therefore, the structure to which the “pull-back” is applied further improves the reliability of memories.

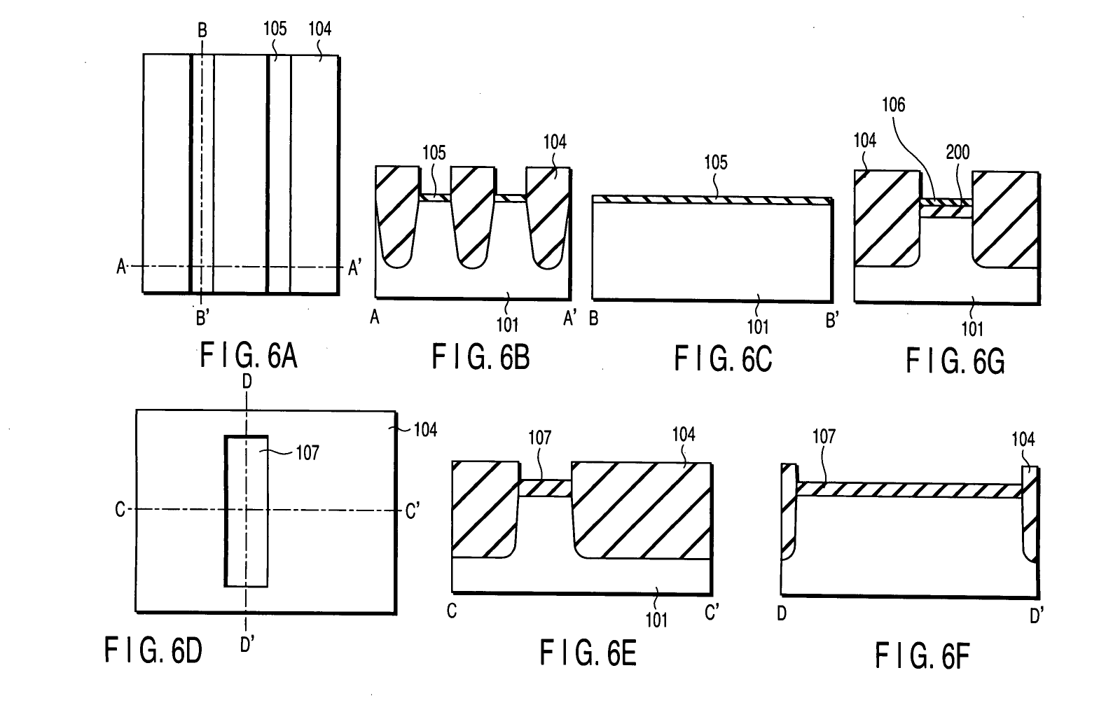

Next, as shown in FIGS. 6A to 6G, by oxidation process such as thermal oxidation or the like, the tunnel insulating film 105 in the memory cell portion (second area), the thin gate insulating film 106 in the logic portion of the control circuit portion (third area) and the thick gate insulating film 107 in the high voltage circuit portion (first area) are formed.

In a case Where the film thickness of the oxide film of the tunnel insulating film 105 is about 8 nm, the film thickness of the oxide film of the thin gate insulating film 106 becomes 3 nm to 5 nm because there is an oxidation prevention layer 200 on the surface of the silicon substrate 101. The film thickness of the thin gate insulating film 106 is adjusted by the nitrogen concentration in the surface of the silicon substrate 101. As the tunnel insulating film 105, a laminated film including a silicon oxide film and a silicon nitride film, or a film of a nitrided silicon oxide film may be also used. Further, the film thickness of the thick gate insulating film 107 becomes about 40 nm, because the oxide film thickness (35 nm) of the silicon oxide film 102T increases when the tunnel insulating film 105 is formed.

As explained above, according to the present embodiment, by only one oxidation process, three kinds of gate insulating films 105, 106 and 107 with different film thickness are formed. Therefore, according to the present embodiment, it is possible to form three kinds of gate insulating films 105, 106 and 107 with different film thickness, without any increase of processes or complexity thereof.

Further, because the tunnel insulating film 105 and the FG electrode 108 are formed after the STI is formed, the process to form the tunnel insulating film 105 and the FG electrode 108 does not cause any limitation to the STI process conditions (for example, formation temperature, atmosphere, and the like). Accordingly, preferable STI is realized. Therefore, operation failures of the products arising from the STI process are prevented.

Further, because the tunnel insulating film 105 is formed after the STI is formed, the tunnel insulating film 105 does not have any process damage arising from the STI process. Thereby, the tunnel insulating film 105 of high reliability is realized. Therefore, the limitation of the number of rewriting times of flash memories increases.

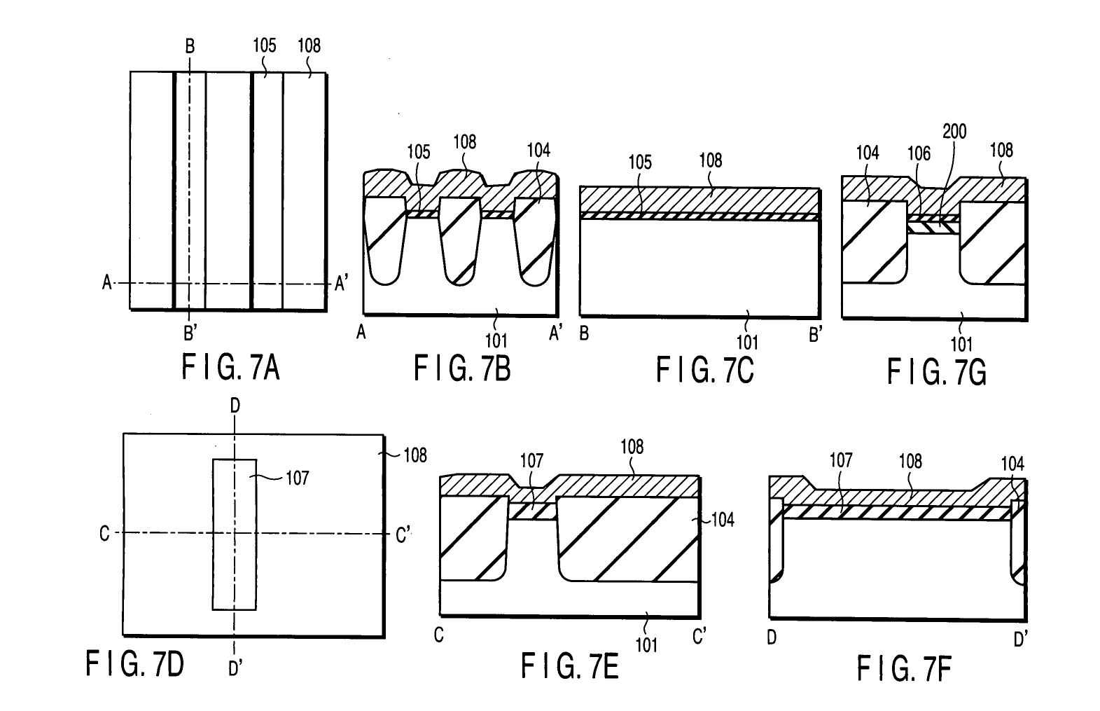

Next, as shown in FIGS. 7A to 7G, by use of LP-CVD process, the first polycrystalline silicon film 108 to be processed into the FG electrode in the memory cell portion and to be processed into a part of the gate electrode in the control circuit portion is deposited on the entire surface. The film thickness of the first polycrystalline silicon film 108 is for example about 40 nm.

Here, the isolation insulating film 104 filled into the STI trench is formed so as to have a stepped portion which is protruded about 30 nm from the surface of the silicon substrate 101. Therefore, it is preferred to set the film thickness of the first polycrystalline silicon film 108 so that the stepped portion is completely filled with the first polycrystalline silicon film 108.

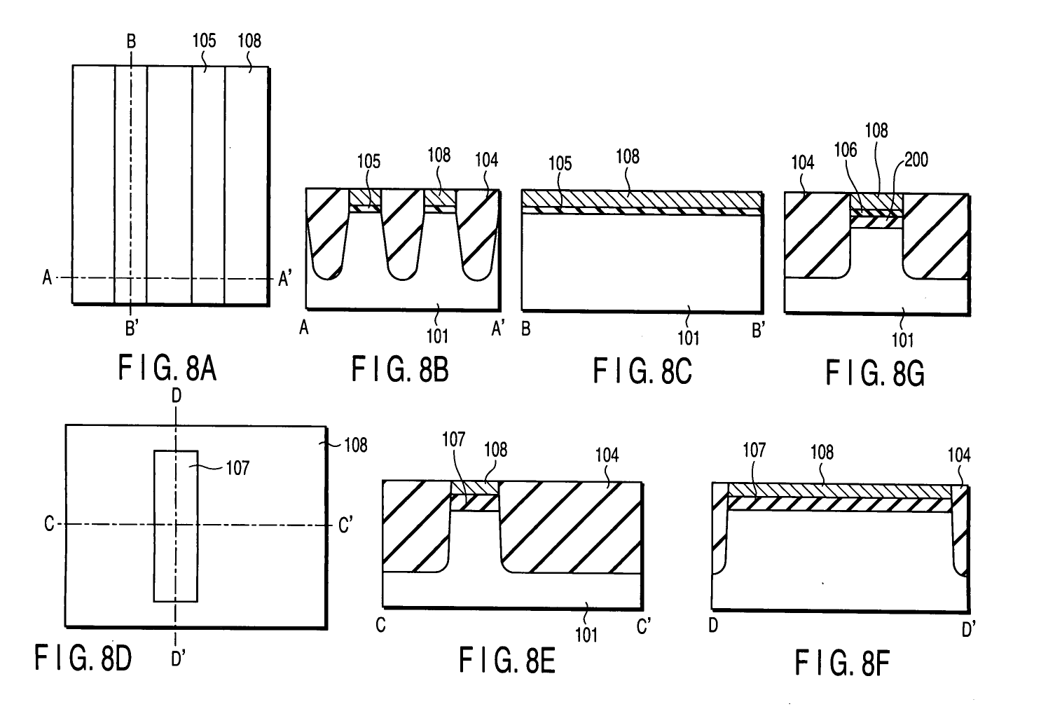

Next, as shown in FIGS. 8A to 8G, by use of CMP process, the entire surface is planarized. As a result, the FG electrode 108 and a part of the gate electrode in the control circuit portion is formed on the surface of the silicon substrate 101 via insulating films 105-107. The FG electrode 108 in the memory cell portion and the gate electrode 108 (first gate electrode) in the peripheral circuit portion are made in a same layer.

In the present embodiment, after the STI is formed, the polycrystalline silicon film to be processed into the FG electrode 108 is formed. Therefore, the growth of grains in the polycrystalline silicon film owing to oxidation process relating to the STI process does not occur. As a result, the FG electrode 108 keeping satisfactory surface morphology is realized. Thereby, the leakage current of the interpoly insulating film 109 owing to concaves and convexes in the surface of the FG electrode 108 is reduced. The reduction of the leakage current improves the yield of products.

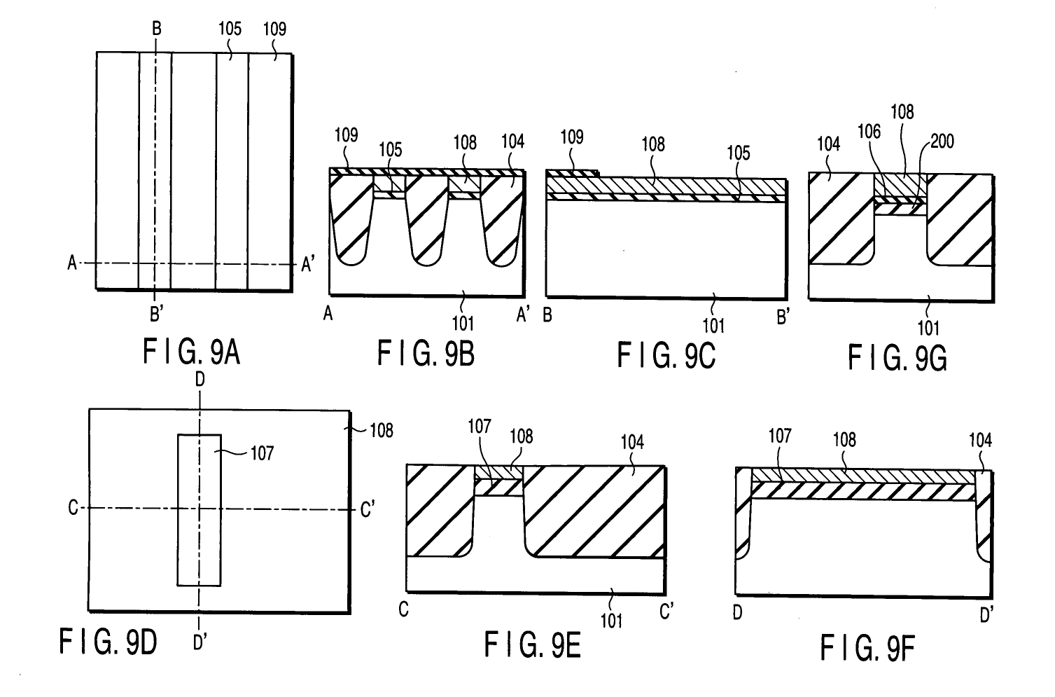

Next, as shown in FIGS. 9A to 9G, the interpoly isolation film 109 is formed on an area including the exposed FG electrode 108.

As the interpoly insulating film 109, an ONO (oxide film-silicon nitride film-oxide film), or a high-k insulating film such as an Al₂O₃ (alumina) film formed by ALD-CVD process and the like may be employed. The film thickness of the Al₂O₃ (alumina) film is for example about 14 nm.

Thereafter, the interpoly insulating film in the region other than the region where a memory cell having a FG structure is formed on, e.g., the interpoly insulating film 109 in the region for a select transistor or a control circuit like that, is selectively removed by etching process using a resist film (not shown) formed by ordinary lithography as a mask.

Here, as an example of high-k insulating film, the Al₂O₃ film is mentioned, meanwhile, leakage current in the Al₂O₃ film is reduced by carrying out heat treatment after the formation of the Al₂O₃ film.

Further, as the high-k film, in the place of the single layer film, laminated films such as an Si₃N₄ (2 nm)/Al₂O₃ (12 nm) film, an Si₃N₄ (1.5 nm)/Al₂O₃ (13 nm)/Si₃N₄ (1.5 nm) film, or an Al₂O₃ (2 nm)/HfO₂/Al₂O₃ film and the like may be employed. The values in the above parentheses show film thickness values.

Further, in the place of Si₃N₄, an SiON film (for example, 1.5 nm) having dielectric constant about 5.5 to 6.0 may be employed. By adopting such multilayer structures, the breakdown voltage of the interpoly insulating film is improved.

As the interpoly insulating film, besides those mentioned above, the followings may be employed.

At first, it is possible to use a hafnium oxide film (HfO₂) in place of the Al₂O₃ film. The HfO₂ film exhibits a dielectric constant of about 20. Therefore, even if the area of the HfO₂ film is small, it is possible to secure a large capacitance. It is also possible to use a Si₃N₄ film of a single layer structure, which exhibits a dielectric constant of about 8, in place of the Al₂O₃ film. Further, it is possible to use the laminate films given below in place of the Al₂O₃ film:
A laminate film of Si₃N₄ (about 2 nm)/Ta₂O₅ (about 20 nm)/Si₃N₄ (about 2 nm);
A laminate film of Si₃N₄ (about 2 nm)/SrTiO₃ (about 30 nm)/Si₃N₄ (about 2 nm);
A laminate film of HfO₂ (about 10 nm)/ALD-Al₂O₃ (about 3 nm);
A laminate film of Si₃N₄ (about 2 nm)/Nd-doped Ta₂O₅ (about 20 nm)/Si₃N₄ (about 2 nm);
A laminate film of Si₃N₄ (about 2 nm)/Ti-dopedoped Ta₂O₅ (about 20 nm)/Si₃N₄ (about 2 nm);
A laminate film of Si₃N₄ (about 2 nm)/barium strontium titanium oxide (Ba, Sr)TiO₃ (about 20 nm)/Si₃N₄ (about 2 nm); and

A laminate film of HfO₂ (about 10 nm)/Al₂O₃ (5 nm)/SiON (1 nm).

As described above, it is possible to obtain the interpoly insulating film by combining a plurality of high-k insulating films. In this case, the coupling capacitance between the CG and FG can be increased.

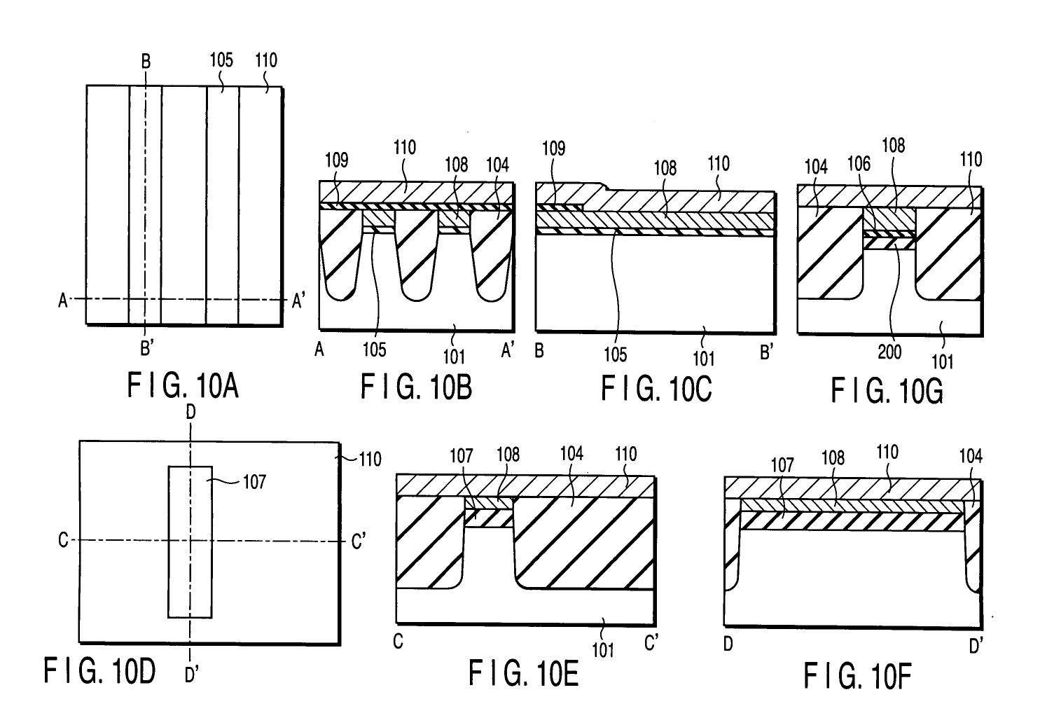

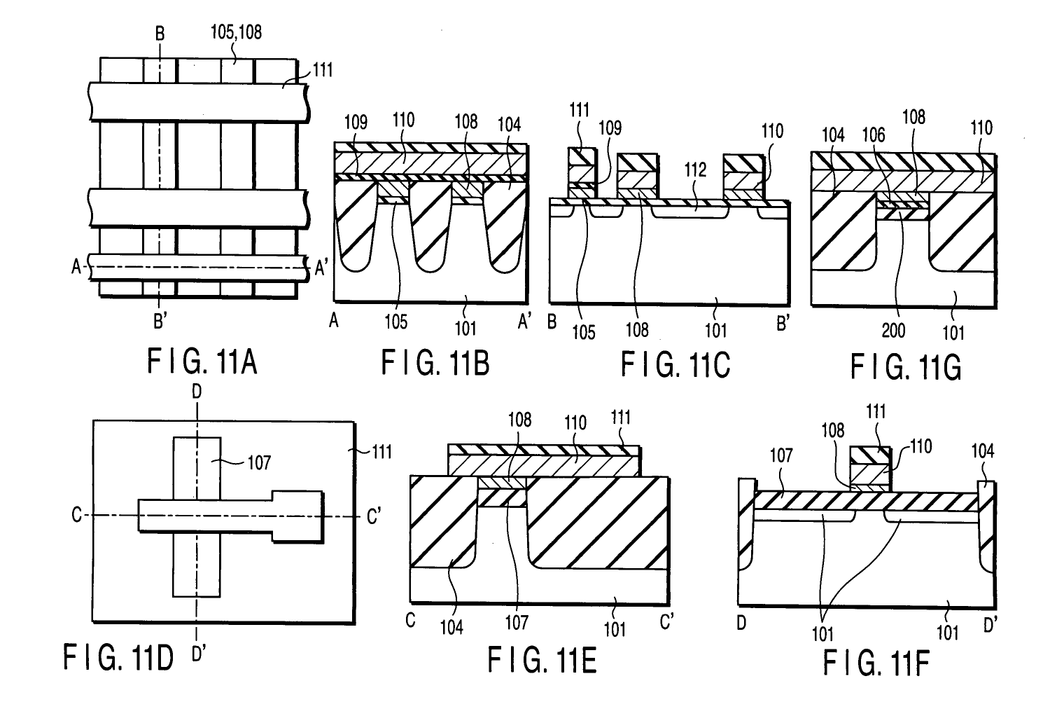

Next, as shown in FIGS. 10A to 10G, the second polycrystalline silicon film 110 to be processed into the CG electrode and the second gate electrode is formed on the entire surface. The film thickness of the second polycrystalline silicon film is for example about 40 nm. Though not directly illustrated in the figure, the interpoly insulating film 109 in other areas than the memory cell portion such as the selection transistor area, the control circuit portion and the high voltage circuit portion and the like has been removed, the first polycrystalline silicon film 108 and the second polycrystalline silicon film 110 are connected in electrically low resistance. As the conductive film to be processed into the CG electrode and the second gate electrode, a metallic silicide film may be employed. Metals in the metallic silicide film are, for example, tungsten (W), cobalt (Co), nickel (Ni) or titanium (Ti).

Next, as shown in FIGS. 11A to 11G, the gate cap insulating film 111 such as an oxide film (SiO₂ film) or a silicon nitride film (Si₃N₄ film) or the like is formed on the second polycrystalline silicon film 110 to be processed into the gate electrode in the transistor in the memory cell portion, the high voltage circuit portion, and the control circuit portion and the like. The film thickness of the gate cap insulating film 111 is for example about 30 nm.

Thereafter, the gate cap insulating film 111, the gate electrode 110, the interpoly insulating film 109, the floating gate electrode 108 are etched sequentially by RIE process using a resist film (not shown) formed by ordinary lithography process as a mask. Etching conditions of the RIE process such as etching gas are appropriately changed according to objectives to be etched.

Next, an oxide film (not shown) is formed on the side wall of the gate electrode 110, thereafter, source/drain diffusion layer 112 of transistor is formed by, for example, ion implantation process and activation anneal process. Here, the source/drain diffusion layer 112 is an N-type layer (extension layer). In the same manners, in the P channel MOSFET area, a p-type source/drain diffusion layer is formed.

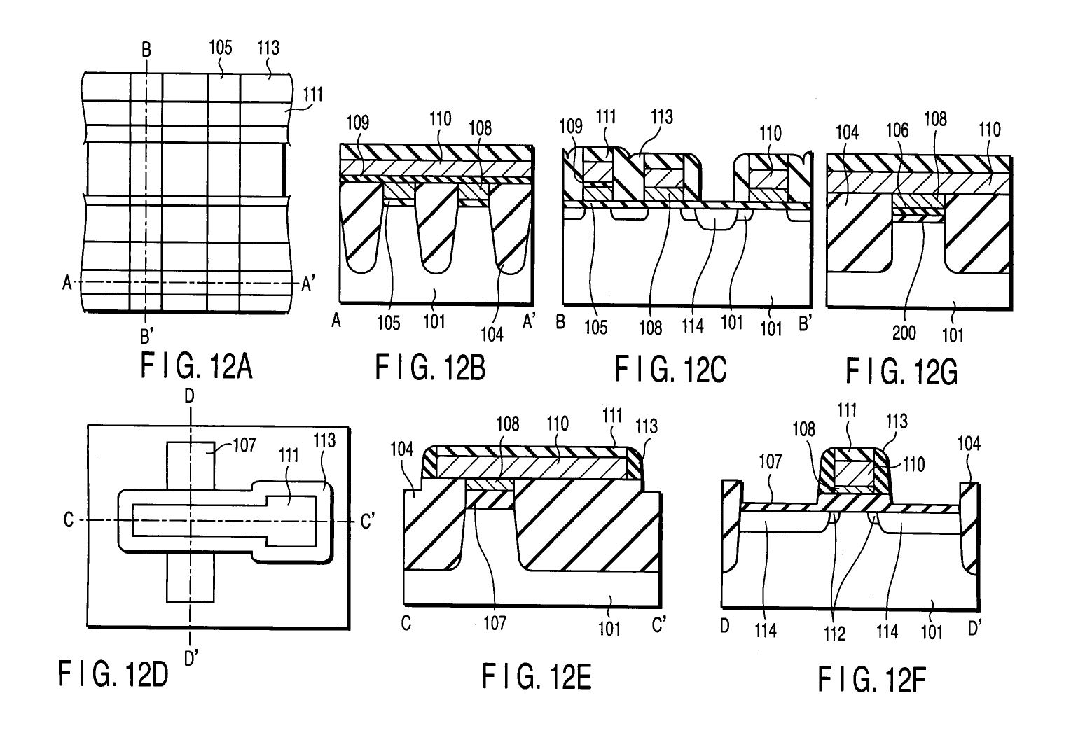

Next, as shown in FIGS. 12A to 12G, a silicon nitride film to be processed into the side wall insulating film 113 is formed on the entire surface, thereafter, the silicon nitride film is etched by ordinary RIE process, thereby the side wall insulating film 113 is formed on the side wall of the gate electrode.

Next, impurity ions are implanted into the surface of the silicon substrate 101 by ion implantation process using a resist film (not shown) formed by ordinary lithography process as a mask, thereafter, the impurity ions are activated by anneal process, thereby a source/drain diffusion layer 114 is formed. Here, the source/drain diffusion layer 114 is an N⁺ type layer. In the same manners, in the P channel MOSFET area, a P⁺ type source/drain diffusion layer is formed.

At this time, in a case where the distance between the CG electrodes 110 is 60 nm or less, as shown in FIGS. 12A to 12G, openings between memory cells are completely filled with the side wall insulating film 113. Therefore, in the next step, the source/drain diffusion layer 114 having high impurity concentration is not formed on the substrate surface between memory cells.

In the present embodiment, explanations has been made with an example where polycrystalline silicon is used as a source material of the gate electrode, while of course, a laminated film such as a laminated film of a polycide film (for example, a WSi₂/polycrystalline silicon film, a CoSi₂/polycrystalline silicon film and the like), or a polymetal film (for example, a W/WN/polycrystalline silicon film and the like) may be used.

Here, though not shown in the figure, halo implant process may be carried out to prevent punch through of transistor in the control circuit portion. Incidentally, if the length of the gate electrode becomes narrow, layers formed by halo implant process tend to be overlapped. Even in such a case, by optimizing ion implantation amount, preferable transistor characteristics are realized.

Next, as shown in FIGS. 13A to 13G, the interlayer insulating film 115 is formed on the entire surface by CVD process. Thereafter, the bit line contact plug layer 116, the bit line 117, the interlayer insulating film 118, the contact plug 119, and the wiring layer 120 are formed sequentially. Then, a passivation film (not shown), a pad (not shown) and so forth are formed, and a semiconductor memory device is complete.

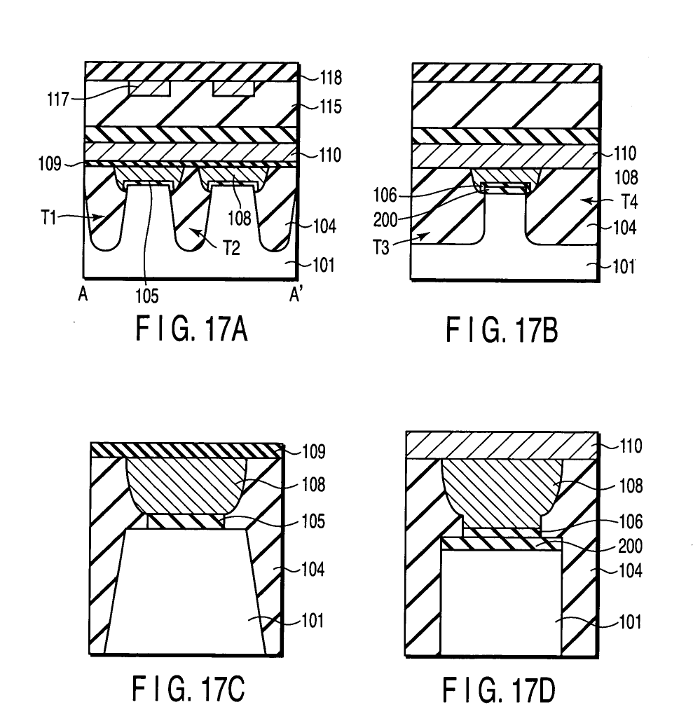

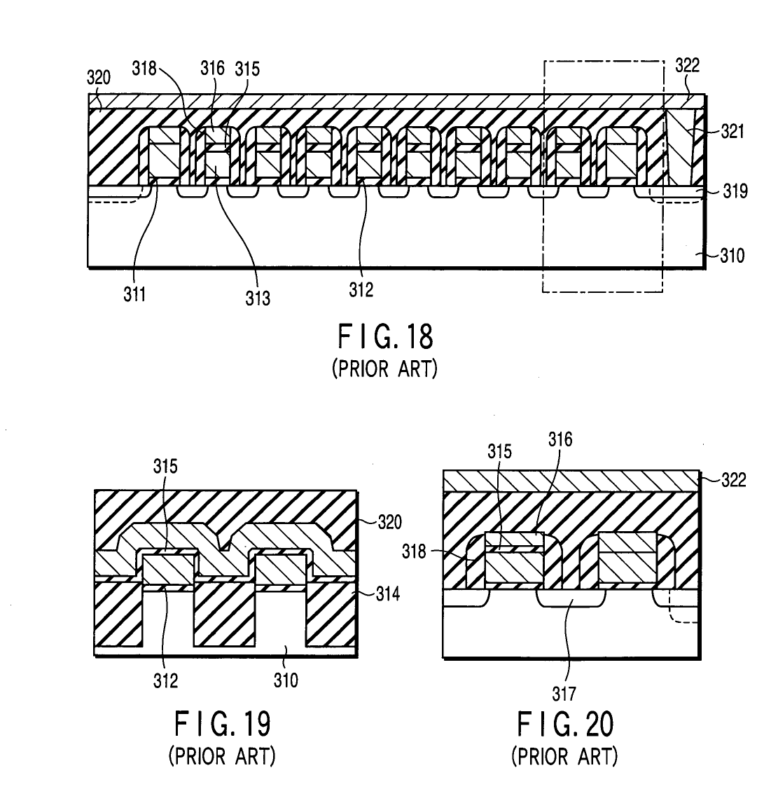

The precise cross sectional shapes of the isolation insulating film 104 are as shown in FIGS. 16A and 16B, and in a case that the isotropic etching amount of the isolation insulating film 104 is increased, the precise cross sectional shapes in FIGS. 13B and 13G becomes as shown in FIGS. 17A and 17B.

As shown in FIG. 17A, the tunnel insulating film 105 is provided on the surface of the silicon substrate 101 that has been exposed in the process in FIG. 16A. That is, the tunnel insulating film 105 is provided on the surface (main surface) of the silicon substrate 101 defined by STI trenches T1 and T2, and on the side surface of the silicon substrate 101 which is not covered with the isolation insulating film 104.

The FG electrode and the first gate electrode 108 are provided so as to fill the concaves that have been made by removing the insulating films 102 and 103 in the process in FIG. 16A. Therefore, the electrode 108, with respect to the dimension in the channel width direction, becomes larger at its top portion than at its bottom portion. As a result, in the peripheral circuit portion, as shown in FIG. 17B, the contact area of the first gate electrode 108 and the second gate electrode 110 increases, thereby, the contact resistance between these gate electrodes 108 and 110 decreases. Therefore, the operation speed of the peripheral circuit is made into a higher speed. For example, the operation speed of the logic circuit is made into a higher speed.

Further, by application of the “pull-back” shown in FIGS. 15A and 15B to FIGS. 17A and 17B, as shown in FIGS. 17C and 17D, there is no need to expose the side surface of the silicon substrate 101. In such shape, the edge portion of the silicon substrate 101 in the active area is covered with the isolation insulating film 104, and the tunnel insulating film 106 is not formed on the edge portion of the silicon substrate 101 in the active area. Therefore, the structure to which the “pull-back” is applied further improves the reliability of memory.

In respect to the channel width direction of the memory cell, the upper side of the FG electrode 108 facing the CG electrode 110 is larger than the lower side of the FG electrode 108 facing the tunnel insulating film 105, therefore the coupling ratio of memory cell increases. Thereby, the miniaturization and reduction of operation voltage of the memory cell are progressed, further, uneven characteristics among memory cells is reduced.

Further, two sides of the FG electrode 108 are formed in self-align manner with the STI area, and remaining two sides of the FG electrode 108 are formed in self-align manner with the CG electrode 110, which contribute to miniaturization of memory cell and reduction of uneven characteristics among memory cells.

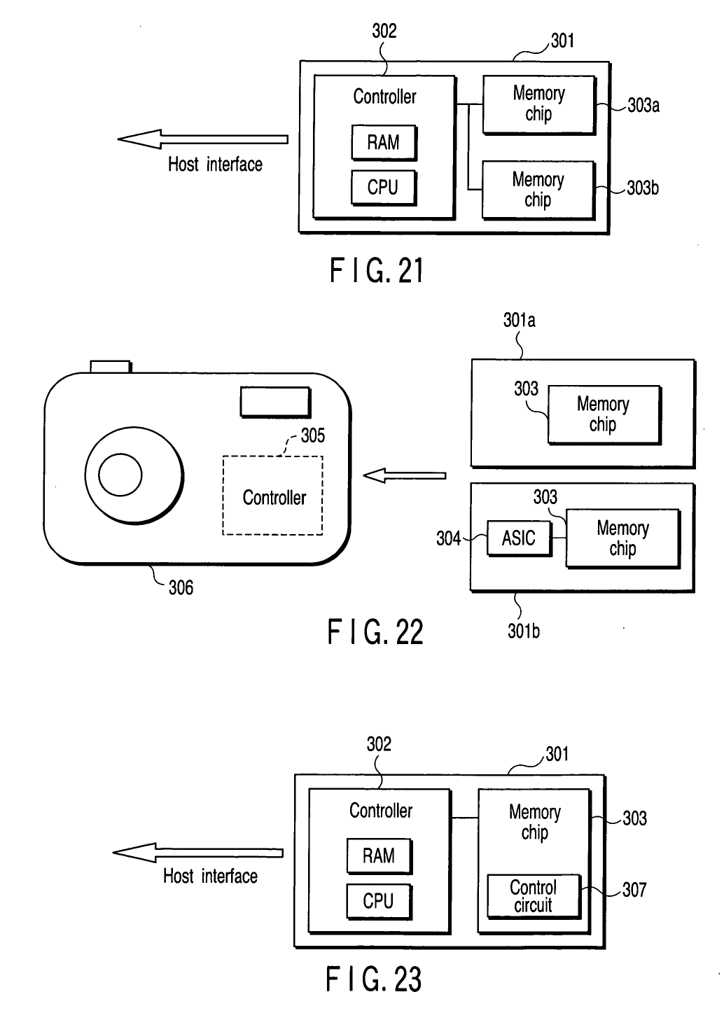

FIGS. 21 to 23 exemplify the devices comprising the NAND flash memory of the embodiment.

FIG. 21 shows a memory card comprising a controller and embedded chips. The controller 302 and memory chips 303a and 303b are mounted on the memory card 301. The memory chips 303a and 303b comprises the NAND flash memory of the embodiment.

The host interface is, for example, an ATA interface, a PC card interface, and USB. It is possible for the other interfaces to be used as the host interface. The controller 302 includes a RAM and a CPU. It is possible for the controller 302 and the memory chips 303a, 303b to be formed in a single chip or to be formed separately in different chips.

FIG. 22 shows a memory card without the controller. This example is directed to a card 301a having a memory chip 303 alone mounted thereto, or a card 301b having a memory chip 303 and a relatively small scale logic circuit (ASIC) 304 mounted thereto. The memory chip 303 includes the NAND flash memory of the embodiment. The apparatus on the host side, to which the cards 301a and 301b are connected, is, for example, a digital camera 306 equipped with a controller 305.

Further, FIG. 23 shows a memory chip with a control circuit. The controller 302 and a memory chip 33 are mounted on the memory card 301. The memory chip 303 includes a control circuit 307.

The present invention is not limited to the embodiments described above. For example, in the embodiments, the present invention is applied to the NAND type semiconductor memory device, however, the present invention is also applied to the NOR type semiconductor memory device. The method of manufacturing the NOR type semiconductor memory device is basically equal to the manufacturing method of the NAND type semiconductor memory device except for the connecting relationship of the transistors. Therefore, the effects similar of the embodiments can also be expected in the case of the NOR type flash memory.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. A semiconductor device comprising:
a semiconductor substrate;
a first isolation area provided on the semiconductor substrate, the first isolation area comprising first and second trenches provided on a surface of the semiconductor substrate; and a first insulating film provided in the first and second trenches and protruding above the surface of the semiconductor substrate, and with respect to a channel width direction, a distance between the first insulating film on the first trench and the first insulating film on the second trench at position higher than the surface of the semiconductor substrate being longer than the distance at a position of the surface; and
an electrically rewritable semiconductor memory cell having the channel width direction and provided on the substrate,
the semiconductor memory cell comprising
a second insulating film provided on the surface of the semiconductor substrate between the first trench and the second trench;
a control gate electrode provided above the second insulating film;
a floating gate electrode provided between the control gate electrode and the second insulating film, with respect to dimension in the channel width direction, an upper side of the floating gate electrode facing the control gate electrode being larger than a lower side of the floating gate electrode facing the second insulating film, and with respect to the channel width direction, displacement of the floating gate electrode to the first and second trenches being approximately equal; and
a third insulating film provided between the floating gate electrode and the control gate electrode.

2. The semiconductor device according to claim 1,
further comprising: a second isolation area provided on the semiconductor substrate and a peripheral circuit portion including a MOS transistor;
the second isolation area comprising third and fourth trenches provided on the surface of the semiconductor substrate and a fourth insulating film provided in the third and fourth trenches and protruding above the surface of the semiconductor substrate, and with respect to a channel width direction of the MOS transistor, a distance between the fourth insulating film on the third trench and the fourth insulating film on the fourth trench at the position higher than the surface of the semiconductor substrate being longer than the distance at the position of the surface;
the MOS transistor comprising a fifth insulating film provided on the surface of the semiconductor substrate between the third trench and the fourth trench; a first gate electrode provided on the fifth insulating film, and with respect to dimension in the channel width direction, a top portion of the first gate electrode being larger than a bottom portion of the first gate electrode; and a second gate electrode provided on the first gate electrode.

3. The semiconductor device according to claim 1,
wherein a distance between the first insulating film on the first trench and the first insulating film on the second trench increases as a position from the surface of the semiconductor substrate becomes higher.

4. The semiconductor device according to claim 2,
wherein distance between the first insulating film on the first trench and the first insulating film on the second trench increases as a position from the surface of the semiconductor substrate becomes higher.

5. The semiconductor device according to claim 1,
wherein with respect to the channel width direction of the semiconductor memory cell, the second insulating film is provided over a region including the surface of the semiconductor substrate and a side surface of the semiconductor substrate below the surface.

6. The semiconductor device according to claim 2,
wherein with respect to the channel width direction of the semiconductor memory cell, the second insulating film is provided over a region including the surface of the semiconductor substrate and a side surface of the semiconductor substrate below the surface.

7. The semiconductor device according to claim 1,
wherein the first insulating film covers edge portion of the semiconductor substrate between the first trench and the second trench, and the second insulating film is not formed on the edge portion.

8. The semiconductor device according to claim 2,
wherein the first insulating film covers edge portion of the semiconductor substrate between the first trench and the second trench, and the second insulating film is not formed on the edge portion.

9. The semiconductor device according to claim 1,
wherein the second insulating film is a tunnel insulating film.

10. The semiconductor device according to claim 9,
wherein the tunnel insulating film includes a laminated film including a silicon oxide film and a silicon nitride film, or an aluminum oxide film.

11. The semiconductor device according to claim 1,
wherein the second insulating film is selected from the group consisting of an oxide film of a single layer containing Al, Ta, Ti, Sr, Hf or Zr, a laminate film including at least two of these oxide films, a laminate film including the oxide film of the single layer and a silicon oxide film, a laminate film including the oxide film of the single layer and a silicon nitride film, a laminate film including the laminate film which includes at least two oxide films of the single layer and a silicon oxide film, and a laminate film including the laminate film which includes at least two oxide films of the single layer and a silicon nitride film.

12. A method of manufacturing a semiconductor device comprising:
forming a first insulating film on a semiconductor substrate;
forming first and second trenches penetrating the first insulating film and reaching a halfway depth of the semiconductor substrate by etching the first insulating film and the semiconductor substrate;
filling the first and second trenches with a second insulating film;
removing the first insulating film by chemical solution process;
forming a third insulating film on a surface of the semiconductor substrate between the first trench and the second trench, the surface being exposed by removing the first insulating film;
forming a floating gate electrode on the third insulating film; the floating gate electrode having a surface which is approximately flush with an upper surface of the second insulating film;
forming a fourth insulating film on the floating gate electrode; and
forming a control gate electrode on the fourth insulating film.

13. A method of manufacturing a semiconductor device comprising:
forming a first insulating film on a first area, a second area and a third area of a semiconductor substrate;
forming an oxidation prevention area in the third area;
removing the first insulating film in the second and third areas;
forming a second insulating film by oxidizing the first, second and third areas, the second insulating film having a film thickness distribution wherein the second insulating film becomes thinner in the order of the first area, the second area, and the third area, and the second insulating film in the first area including the first insulating film;
forming a first gate electrode on the second insulating film;
forming a third insulating film on the first gate electrode in the second area; and
forming a second gate electrode on the third insulating film in the second area and on the first gate electrode in the first and third areas.

14. A method of manufacturing a semiconductor device comprising:
forming a first insulating film on a first area, a second area and a third area of a semiconductor substrate;
forming an oxidation prevention area in the third area;
forming first and second trenches penetrating the first insulating film and reaching a halfway depth of the semiconductor substrate by etching the first insulating film in the second area and the semiconductor substrate;
filling the first and second trenches with a second insulating film;
removing the first insulating film in the second and third areas by chemical solution process;
forming a third insulating film by oxidizing the first, second and third areas, the third insulating film having a film thickness distribution wherein the third insulating film becomes thinner in the order of the first area, the second area, and the third area, and the third insulating film in the first area including the first insulating film;
forming a first gate electrode on the third insulating film, the first gate electrode having a surface which is approximately flush with an upper surface of the second insulating film in the second area;
forming a fourth insulating film on the first gate electrode in the second area; and
forming a second gate electrode on the fourth insulating film in the second area and on the first gate electrode in the first and third areas.

15. The method of manufacturing a semiconductor device according to claim 13,
wherein the third insulating film in the second area is a tunnel insulating film.

16. The method of manufacturing a semiconductor device according to claim 15,
wherein the tunnel insulating film includes a laminated film including a silicon oxide film and a silicon nitride film, or an oxide aluminum film.

17. The method of manufacturing a semiconductor device according to claim 13,
wherein the third insulating film in the second area is a tunnel insulating film.

18. The method of manufacturing a semiconductor device according to claim 17,
wherein the tunnel insulating film includes a laminated film including a silicon oxide film and a silicon nitride film, or an oxide aluminum film.

19. The method of manufacturing a semiconductor device according to claim 14,
wherein the third insulating film in the second area is a tunnel insulating film.

20. The method of manufacturing a semiconductor device according to claim 19,
wherein the tunnel insulating film includes a laminated film including a silicon oxide film and a silicon nitride film, or an oxide aluminum film.
